(19) United States
(12) Patent Application Publication
(10) Pub. No.: US 2009/0152653 A1
(43) Pub. Date: Jun. 18, 2009

(54) Surface mount multi-axis electronics package for micro-electrical mechanical systems(MEMS) devices

(76) Inventors: Hamid R. Borzabadi, Noblesville, IN (US); Ronald D. Wilcox, Burton, MI (US)

Correspondence Address: DELPHI TECHNOLOGIES, INC., M/C 480-410-202, PO BOX 5052, TROY, MI, 48007, US

(21) Appl. No.: 12/002,065

(22) Filed: Dec. 14, 2007

(51) Int. Cl. H01L 29/84; H01L 21/50

(52) U.S. Cl. 257/415; 438/51; 257/E29.324; 257/E21.499

(57) ABSTRACT

A surface mount multi-axis cavity package for micro-electrical mechanical systems (MEMS) devices includes a substantially cubical housing having a plurality of sides and at least one internal cavity. A first plurality of solder pads are positioned on at least one side of the housing and a second plurality of solder pads are positioned on a bottom of the housing. A MEMS sensor is then mounted within the at least one internal cavity in any axis for increasing the versatility of the MEMS device.

### TECHNICAL FIELD

The present invention relates generally to electronics packaging and more particularly to electronic packaging for micro-electrical mechanical system (MEMS) devices.

### BACKGROUND OF THE INVENTION

Electro-Mechanical Systems (MEMS) is the integration of mechanical elements, sensors, actuators, and electronics on a common silicon substrate through microfabrication technology. While the electronics are fabricated using integrated circuit (IC) process sequences (e.g., CMOS, Bipolar, or BICMOS processes), the micromechanical components are fabricated using compatible “micromachining” processes that selectively etch away parts of the silicon wafer or add new structural layers to form the mechanical and electro-mechanical devices. MEMS brings together silicon-based microelectronics with micromachining technology, making possible the realization of complete systems-on-a-chip devices. MEMS is an enabling technology allowing the development of smart products, augmenting the computational ability of microelectronics with the perception and control capabilities of microsensors and microactuators and expanding the space of possible designs and applications.

While microelectronic ICs work to control functional processing steps in the system, MEMS augments this decision-making capability to allow microsystems to sense and control the environment. Thus, the primary applications of MEMS technology include sensors that gather information from the environment through measuring such parameters as mechanical, thermal, bio-logical, chemical, optical, and magnetic phenomena. The MEMS electronics then process the information derived from the sensors and, through some decision-making capability, direct the actuators to respond by controlling the environment for some desired outcome or purpose. Because MEMS devices are manufactured using batch fabrication techniques similar to those used for integrated circuits, unprecedented levels of functionality, reliability, and sophistication can be achieved using small silicon MEMS chips at a relatively low cost.

In MEMS applications, such as automotive sensors, such as those having accelerometer or gyroscopic applications, it is often required for the sensor to be used in multiple applications with different axis of sensing. Normally, silicon-based sensors (MEMs) are designed to be sensitive in one axis with little or no sensitivity in other axis. In order for the sensor to be used in other axis, the surrounding MEMS device package must be designed to accommodate the specified orientation with variations in either an X, Y, or Z axis.

Prior art FIG. 1 illustrates a MEMS sensor package 100 oriented in a stand-up position where pins 101 are positioned to extend vertically from a body 103 where they are attached to a PC board. This type of MEMS package is generally required to withstand severe shock and vibration in safety applications such as vehicular frontal crash or roll over with an accordance of ±1 degree. In the past in order to meet these requirements, the sensor module was manufactured with “through hole” technology rather than surface mount technology (SMT). Similarly, FIG. 2 illustrates an example of a surface mounted MEMS sensor package 200 where the pins 201 extend from a flat package 203 whose body rests on the surface of a PC board. This type of MEMS device might be used depending on the required mounting axis. However, the utilization of separate packaging technologies tends to be costly both for the product manufacturing and its testing.

### SUMMARY OF THE INVENTION

An embodiment of the present invention is directed to a surface mount multi-axis cavity package for micro-electrical mechanical systems (MEMS) devices that includes a substantially cubical housing having at least one internal cavity. A first group of solder pads are positioned on at least one side of the housing and a second group of solder pads are positioned on a bottom of the housing. A MEMS sensor is mounted within the internal cavity and a lead frame is positioned within a wall of the cubical housing for interconnecting the first group of solder pad connections and the second group of solder pad connections. The multi-axis package is very advantageous as it allows a MEMS device to be mounted within the package on its X or Y axis such that the package can then be connected on a printed circuit board for increasing the overall versatility of the MEMS device

These and other features, advantages, and objects of the present invention will be further understood and appreciated by those skilled in the art by reference to the following specifications, claims, and appended drawings.

### BRIEF DESCRIPTION OF THE FIGURES

The present invention will now be described, by way of example, with reference to the accompanying drawings, in which:

FIG. 1 is prior art diagram illustrating a stand-up MEMS sensor package;

FIG. 2 is prior art diagram illustrating a surface mounted MEMS sensor package;

FIG. 3 illustrates a surface mounted multi-axis cavity package for MEMS devices in accordance with an embodiment of the invention;

FIG. 4 a cross-sectional view of the surface mounted multi-axis cavity package through section lines IV-IV as shown in FIG. 3;

FIG. 5 is a cross-sectional view of the surface mounted multi-axis cavity package through section lines V-V as shown in FIG. 3;

FIG. 6 is a diagram illustrating use of a MEMS device on a printed circuit board with compliant pin outs;

FIG. 7 is a diagram illustrating use of a MEMS device on a print circuit board using a wire bond technique; and

FIG. 8 and FIG. 9 are cross-sectional diagrams illustrating use of the invention in a bottom and side mounting configuration.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION OF THE PREFERRED EMBODIMENTS

Before describing in detail embodiments that are in accordance with the present invention, it should be observed that the embodiments reside primarily in combinations of method steps and apparatus components related to a surface mount multi-axis cavity package for with use with a microelectrical mechanical system (MEMS) device. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of microelectrical mechanical system (MEMS) packaging device described herein. The non-processor circuits may include, but are not limited to, a radio receiver, a radio transmitter, signal drivers, clock circuits, power source circuits, and user input devices. As such, these functions may be interpreted as steps of a method to construct a microelectrical mechanical system (MEMS) packaging device. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

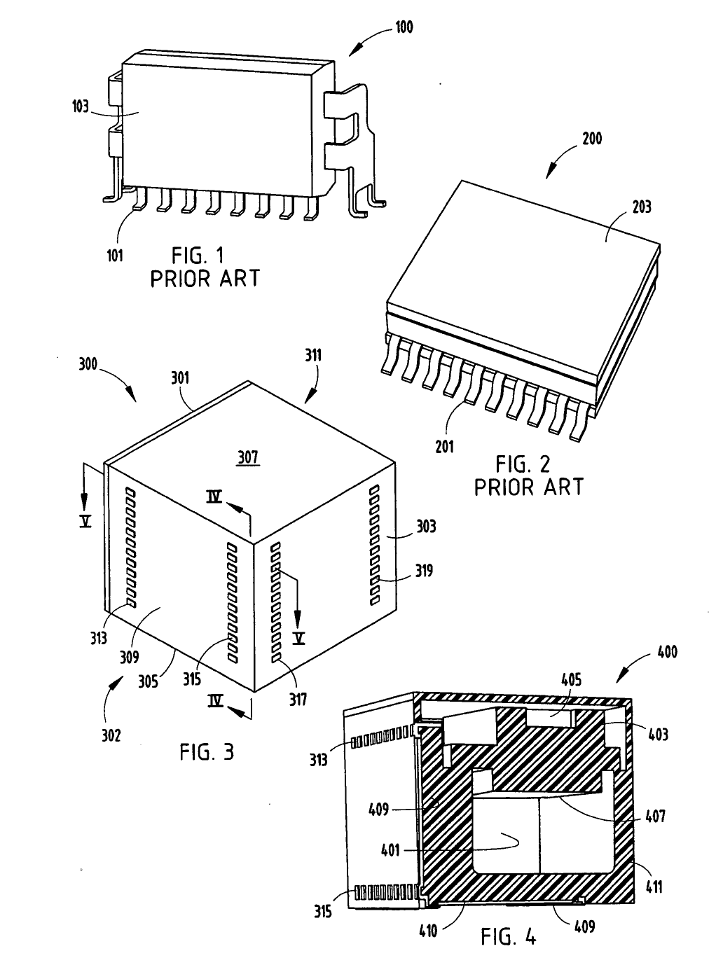

FIG. 3 illustrates a surface mounted multi-axis cavity package 300 for MEMS devices in accordance with an embodiment of the invention. The package 300 is a substantially cubic-like housing 302 having a lid or top 301, bottom 303, side 305, side 307, end 309, and end 311. The top 301 may be removable from the package 300 for access to an internal device (not shown) located within an internal cavity (not shown). The package 300 is constructed of a plastic, FR-4, or like material and is used to hold a MEMS package internally allowing a MEMS sensor device to be oriented and/or mounted to a PC board in any type of horizontal or vertical configuration. This is accomplished using a plurality of solder pads 313, 315, 317, 319 that are positioned on the bottom 303 and side 305 of the package 300. The solder pads 313, 315 are positioned on the side 305 such that the cubic-like package can be positioned flat on top of a PC board where solder may be reflowed to the pads in a conventional style of solder oven manufacturing process. Similarly, solder pads 317, 319 are positioned on the bottom 303 of the package 300 allowing it to positioned with the bottom side flat to the surface of a PC board. Whether the solder pads on either the bottom 303 or the side 305 of the package 300 will depend upon the orientation of the MEMS device oriented in an inside cavity as described herein.

FIG. 4 a cross-sectional view of the surface mounted multi-axis cavity package through section lines IV-IV as shown in FIG. 3. The cross-sectional view of the package 400 includes one or more voids or cavities 401 for allowing a MEMS package 403 to be oriented inside the cavity in an X or Y direction depending on application. A MEMS sensor 405 is mounted within the MEMS package 403 onto a PC board 407. The MEMS sensor 405 typically may be an accelerometer or gyroscopic device such that its orientation is critical to proper operation. The interior of the package 400 may include one or more mounting structures 409, 411 for allowing the MEMS package 403 and PC board 407 to be mounted into a fixed position. As seen in FIG. 4, a plurality of lead frames 409 are wires or substantially thin strips of metal that acts like a PC circuit board trace for electrically connecting the selective solder pads together. Each lead frame 409 is positioned within a wall 410 of the package 400 and allows each pad connected by the lead frame 409 to be interconnected no matter where it is located on the package 400. This allows the MEMS sensor to have great versatility since package 400 can be connected to each respective lead frame 409 and thus mounted in any X-Y orientation since each interconnected pad on the side or bottom of the housing will have the same continuity.

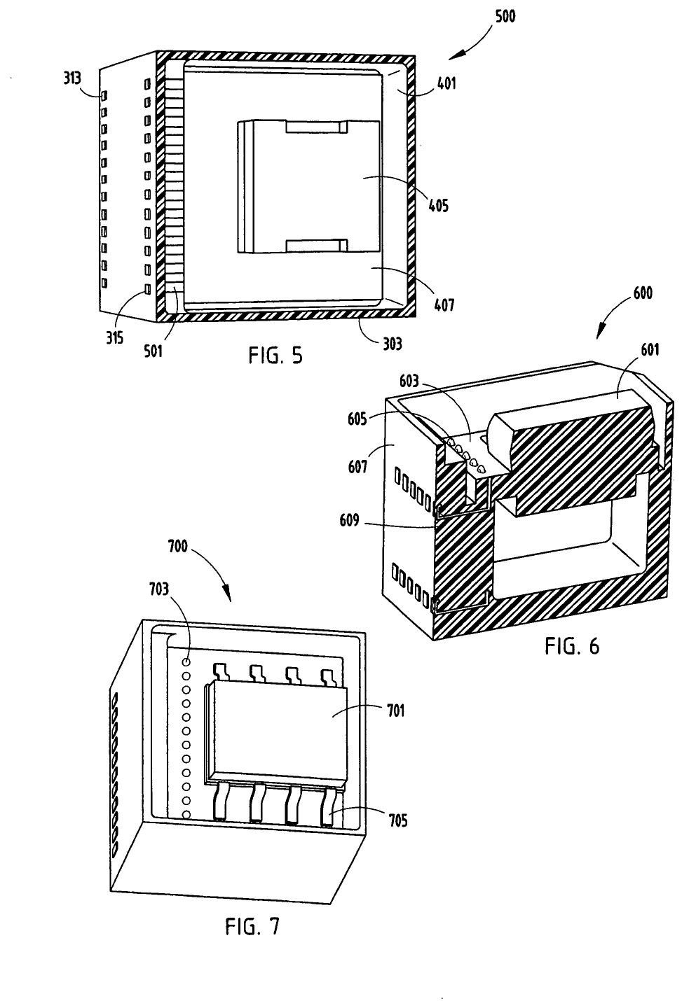

FIG. 5 is a cross-sectional view of the surface mounted multi-axis cavity package through section lines V-V as shown in FIG. 3. The package 500 shows the sensor package 405 mounted onto the PC board 407. One or more wire bonds 501 are attached from the PC board 407 to the various solder pads 313, 315. Although shown in a vertical-like configuration in an “x” axis, those skilled in the art will recognize the invention has the versatility to orient the sensor package 405 substantially 90 degrees inside the cavity 401 such that solder pads along the bottom could be used. Alternatively, a smaller sensor package 405 could be used to orient the device in a “y” axis.

FIG. 6 is a diagram 600 illustrating use of the a MEMS device on a printed circuit board with compliant pin outs. A MEMS device 601 is mounted to a PC board 603 having a plurality of compliant pin outs 605. These pin outs 605 are oriented in the multi-axis cavity package 607 such that one or more lead frames 609 can be connected to each corresponding pin out 605. Similarly, FIG. 7 is a diagram illustrating use of the multi-axis package 700 having a MEMS device 701 mounted on a print circuit board 703 using a wire bond technique. In this embodiment, the PC board and its associated pin outs 703 can be wire bonded 705 to a particular lead frame each connecting to a solder pads on the multi-axis package 700.

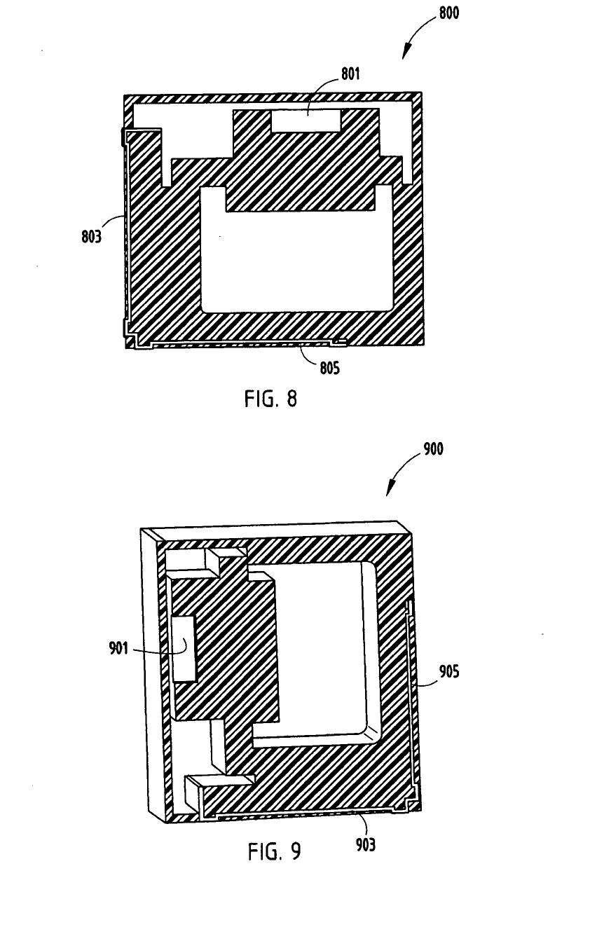

Finally, FIG. 8 and FIG. 9 are cross-sectional diagrams illustrating use of the invention in a bottom and side mounting configuration. FIG. 8 illustrates the use the multi-axis package 800 where an internally mounted MEMS device 801 is positioned in an upright manner allowing the multi-axis package 800 to be mounted such that the solder pads connected to lead frame 803 or solder pads connected to lead frame 805 can be used for connection. Similarly, FIG. 9 illustrates the multi-axis package 900 rotated 90 degrees such that the MBMS device 901 is now oriented on a side of the multi-axis package. Solder pads connected to lead frame 903 or solder pads connected to lead frame 905 can be used for connection. Both FIGS. 8 and 9 illustrate the versatility of the invention as it allows a MEMS device to be mounted in either its X or Y axis. This is very advantageous since it allows existing “off the shelf” MEMS packages to be used in various orientations without the high cost and expense associated with MEMS package tooling and redesign.

Thus, the present invention is directed to a surface mount multi-axis cavity package for MEMS sensor that can be mounted in multiple orientations. The multi-axis packages utilizes a leadfame that is insert molded in high temperature thermoplastic with exposed surfaces in a side and bottom of the package for solder mounting to a PC board. Inside the package cavity, a sensor and mating sensor are mounted to ceramic and/or organic circuit board via a flip chip technique or wirebonding. The PC board is connected to the package via wire bonding or other compliant pin outs. The multi-axis package can be used with a single integrated sensor, such as bare die or pre-packaged, as well as a two chip sensor, such as a sensor and application specific integrated circuit (ASIC) combination. After the sensor is packaged within the cube, it can be covered by a top or lid such that the multi-axis package can be mounted in any needed application.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. A surface mount multi-axis cavity package for micro-electrical mechanical systems (MEMS) devices comprising:
a substantially cubical housing having at least one internal cavity;
a first plurality of solder pads positioned on at least one side of the housing;
a second plurality of solder pads positioned on a bottom of the housing; and
wherein a MEMS sensor is mounted within the at least one internal cavity.

2. A surface mount multi-axis cavity package as in claim 1, further comprising:
at least one lead frame positioned within a wall of the substantially cubical housing for interconnecting the first plurality of solder pad connections and the second plurality of solder pad connections to the MEMS sensor.

3. A surface mount multi-axis cavity package as in claim 1, wherein the package can be soldered to a printed circuit board either in a first axis or in a second axis depending on requirements of the sensor.

4. A surface mount multi-axis cavity package as in claim 1, wherein the substantially cubical housing includes a top for gaining access to the at least one internal cavity.

5. A surface mount multi-axis cavity package as in claim 1, wherein the MEMS sensor is connected to the first plurality and second plurality of solder pads using a wire bond.

6. A surface mount multi-axis cavity package as in claim 1, wherein the MEMS sensor is an accelometer.

7. A surface mount multi-axis cavity package as in claim 1, wherein the MEMS sensor is a gyroscopic device.

8. A surface mount multi-axis cavity package as in claim 1, wherein the MEMS sensor is used in a vehicle.

9. A multi-axis packaging device for use with a MEMS sensor for mounting to a printed circuit board (PCB) comprising:
a substantially cubical housing having a lid for accessing an internal cavity;
a first set of solder pad connections located on at least one side of the substantially cubical housing for connection to the PCB;
a second set of solder pad connections located on a bottom of the substantially cubical housing for connection to a PCB; and
at least one lead frame positioned within a wall of the substantially cubical housing for interconnecting the first set of solder pad connections and the second set of solder pad connections to the MEMS sensor.

10. A multi-axis packaging device as in claim 9, wherein a MEMS sensor is mounted within the internal cavity.

11. A multi-axis packaging device as in claim 9, wherein the MEMS sensor is an accelometer.

12. A multi-axis packaging device as in claim 9, wherein the MEMS sensor is a gyroscopic device.

13. A multi-axis packaging device as in claim 9, wherein MEMS sensor is used in a vehicle.

14. A multi-axis packaging device as in claim 9, wherein the substantially cubical housing can be soldered to a printed circuit board either in a first axis or in a second axis according to sensor requirements.

15. A method for packaging a micro-electrical mechanical systems (MEMS) device in a multi-axis cavity package comprising the steps of:
providing a substantially cubical housing having at least one internal cavity;
positioning a first plurality of solder pads on at least one side of the housing;
positioning a second plurality of solder pads on a bottom of the housing; and
mounting a MEMS sensor within the at least one internal cavity.

16. A method for packaging a MEMS device as in claim 15, further comprising the step of:
positioning at least one lead frame within a wall of the substantially cubical housing for interconnecting the first plurality of solder pad connections and the second plurality of solder pad connections with the MEMS sensor.

17. A method for packaging a MEMS device as in claim 15, further comprising the step of:
soldering the cubical housing to a printed circuit board either in a first axis or in a second axis depending on requirements of the sensor.

18. A method for packaging a MEMS device as in claim 15, further comprising the step of:
providing a lid for accessing the at least one internal cavity.

19. A method for packaging a MEMS device as in claim 15, further comprising the step of:
connecting the MEMS sensor to the first plurality of solder pads or second set of solder pads using a wire bond.

20. A method for packaging a MEMS device as in claim 15, wherein the MEMS sensor is an accelometer.

21. A method for packaging a MEMS device as in claim 15, wherein the MEMS sensor is a gyroscopic device.

22. A method for packaging a MEMS device as in claim 15, wherein the MEMS sensor is used in a vehicle.
